(19) United States
(12) Patent Application Publication
(10) Pub. No.: US 2010/0171516 A1
(43) Pub. Date: Jul. 8, 2010

(54) APPARATUS FOR MEASURING VARIATIONS OF EXTRA-CELLULAR MEMBRANE POTENTIAL WITH MICROELECTRODES

(75) Inventors: Bruno Buisson, Marseille (FR); Ester-Marie Armougom-Steidl, Nans Les Pins (FR)

Correspondence Address: YOUNG & THOMPSON, 209 Madison Street, Suite 500, Alexandria, VA, 22314, US

(73) Assignee: NEUROSERVICE, Marseille Cedex 09 (FR)

(21) Appl. No.: 12/376,867

(22) PCT Filed: Aug. 6, 2007
(86) PCT No.: PCT/EP07/58112

§ 371 Date: May 11, 2009

(30) Foreign Application Priority Data
Aug. 9, 2006 (FR) 0653325

(51) Int. Cl. G01R 27/08

(52) U.S. Cl. 324/692

(57) ABSTRACT

An apparatus includes a substrate plate (12), a set (16) of microelectrodes arranged on the upper face (14) of the substrate plate (12) and a tank (24) which is capable of containing living cells and an perfusion liquid, and which includes a vertical cylindrical lateral skirt (36) which is open towards the top and which surrounds an area including the set (16) of microelectrodes; characterized in that the lateral skirt (36) is attached in a sealed and detachable way with respect to the substrate plate (12).

### TECHNICAL FIELD OF THE INVENTION

The present invention relates to an apparatus for measuring variations of extra-cellular membrane potential, changes which are associated with the activity of living cells, whereby these cells may be isolated cells or cells belonging to a cell tissue.

Such an apparatus, also called a cellular potential measurement apparatus, is notably used in the field of electrophysiology in order to measure potential variations or changes which are associated with different types of activities of excitable cells or excitable tissues such as for example nerve or muscle tissues.

### BACKGROUND OF THE INVENTION

In order to measure such potential variations, it is known how to use an apparatus of the type including a so-called substrate plate on the upper face of which a set or network of microelectrodes is arranged.

The globally planar substrate plate in an insulating material thus bears a set of microelectrodes arranged according to a determined pattern forming a measuring area on which the cells or tissues are placed, on which the measurements should be carried out.

By using a plurality of microelectrodes, it is possible to have many points available at which measurements of potential variations may be carried out.

The substrate plate is for example in glass, or in another insulating material, and it bears on its upper face the network of microelectrodes in a thin layer.

Such an apparatus also includes a tank capable of containing living cells on which measurements should be carried out, as well as a liquid perfusion solution, also called an perfusion liquid with which the tissues or cells may be kept alive.

This tank is essentially formed by a cylindrical lateral, or side, skirt with a vertical orientation which extends upwards above the substrate plate and which surrounds the area including the set of microelectrodes.

Thus, the tank is capable of containing a determined amount of perfusion liquid.

In a known way, the tank is essentially formed by a circular cylindrical lateral skirt in a synthetic material, for example in polystyrene, the lower end section of which is attached, or fixed, by adhesive bonding onto the upper face of the substrate plate, around the area including the microelectrodes.

Conditions for extra-cellular recordings of cell tissues such as slices of brain, by means of networks of microelectrodes (also called Multi Electrode Arrays (MEA)) require control of different parameters of the perfusion liquid used which is provided by perfusion above the upper surface of the cell tissue, and notably by means of its oxygen gas and carbon dioxide content for controlling the pH of the liquid.

The whole of the parameters and of the perfusion conditions are determining for the quality of the performed measurements.

In a known way, notably in order to control the oxygen content of the perfusion liquid, the tank of the apparatus is continuously supplied from a reservoir containing physiological saline.

For this purpose, a so-called carbogen gas containing for example 95% of oxygen gas and 5% of carbon dioxide gas is introduced into the reservoir. For this purpose, the known apparatuses and installations then include controlled means for supplying the tank and pumping from the tank so that perfusion liquid permanently flows in the latter.

The means for providing such a flow should further ensure the presence of a constant amount of liquid in the tank, notably so that it does not overflow because of its very small standardized height.

For example, in a known way, the total available volume of the tank is about 1 ml and its inner diameter is about 18 mm.

Such a known apparatus which resorts to continuous flow of the perfusion liquid, for example with a flow rate of the order of 1 to 3 ml/min, results in a very large consumption of perfusion liquid.

Further, control of the actual parameters and conditions in the tank for measurements is particularly complex.

The very small height of the tank, i.e., of its vertical lateral skirt, and therefore its small total volume, is required so that the operator may easily place cells or cell tissues on the area including microelectrodes.

The object of the present invention is to propose an enhanced design of such an apparatus so that the tank may notably contain a large volume of perfusion liquid solution, in order to suppress the means for continuously supplying the tank with perfusion liquid, while allowing easy placement of the cells or of the cell tissues.

The invention is also directed to being usable with standardized microelectrode networks of known types and dimensions.

### SUMMARY OF THE INVENTION

For this purpose, the invention proposes an apparatus of the type mentioned earlier, characterized in that the lateral skirt of the tank is attached in a sealed and detachable way with respect to the substrate plate.

It is thereby possible to use a skirt with a large height as compared with those of the prior art, this skirt may be placed on the substrate plate after placing the cells and cell tissues.

According to other features of the invention:
the tank includes an annular bottom which is added onto the substrate plate and which surrounds said area including said set of microelectrodes;
the lateral skirt is attached in a sealed and detachable way on the annular bottom of the tank;
the lateral skirt is screwed relatively to the substrate plate;
the lateral skirt is screwed on the annular bottom of the tank;
the lower section of the lateral skirt of the tank is screwed on a radially outer lateral wall of the annular bottom;
the tank is capable of containing about 3 to 50 ml of perfusion liquid;
the quotient of the height of the lateral skirt divided by its largest inner dimension is larger than or equal to 1;
the lateral skirt is circular cylindrical, and its inner diameter is larger than or equal to 5 mm;
the height of the lateral skirt is larger than or equal to 5 mm;
the apparatus includes means for automatically handling the volume and the composition of the perfusion liquid, of the type including a filling and emptying tube which plunges into the tank vertically, which is connected to a robot which sequentially controls the filling and emptying of the tank;
the tube is supported by a gantry, the displacements of which relatively to the tank are controlled along three orthogonal axes;
the automatic handling means include means for controlling the temperature of the perfusion liquid.

### BRIEF DESCRIPTION OF THE FIGURES

Other features and advantages of the invention will become apparent upon reading the following detailed description, wherein, in order to understand it, reference will be made to the appended drawings wherein:

FIG. 1 is a schematic top view of a substrate plate without the tank;

FIG. 2 is an exploded perspective schematic view of the substrate plate and of the tank with a lateral skirt which may be disassembled according to the invention;

FIG. 3 is a diagram illustrating the use of an apparatus according to the invention with a lateral skirt which may be disassembled; and

FIG. 4 is a diagram illustrating an automated installation integrating an apparatus according to the invention.

### DETAILED DESCRIPTION OF THE FIGURES

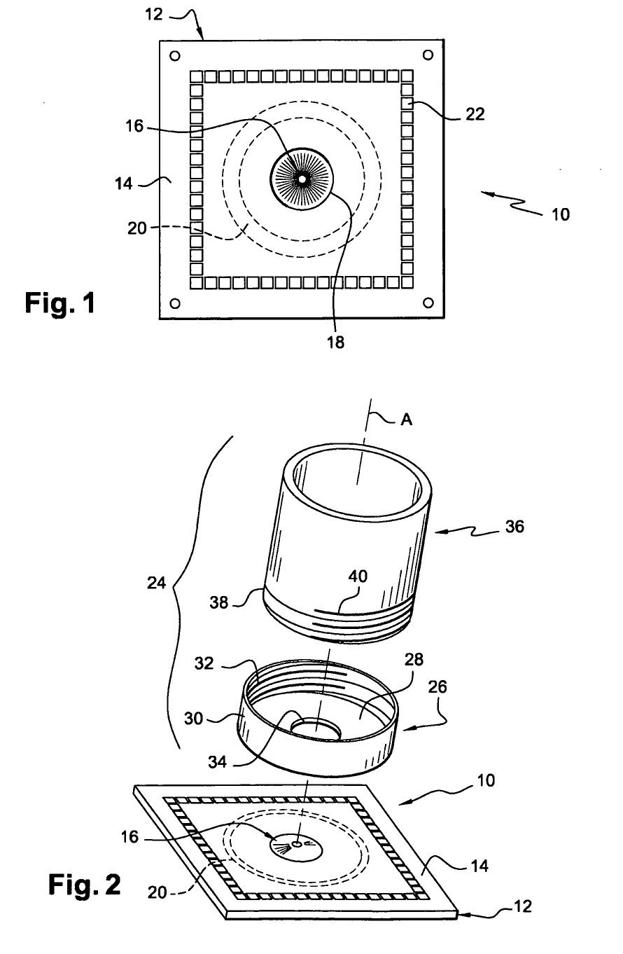

A multi-electrode (MEA) plate 10 is schematically illustrated in FIG. 1, which plate essentially consists of a planar substrate plate 12 in an insulating material, which bears at the centre of its upper face 14, a network of microelectrodes 16 which are arranged in a central area 18 which may have a circular contour as illustrated by way of example.

The microelectrodes are connected to electric connection pads 22 which are arranged here as a square on the upper face 14 and at the periphery of the plate 12.

The length of each side of the square plate 12 is about 50 mm, whereas the diameter of the area 18 is about 10 mm.

As this may be seen in FIG. 2, a tank 24 according to the invention, also called an perfusion tank, is made here in two lower 26 and upper 36 parts.

The first lower part 26, along the vertical orientation of the general axis A of the tank 24, is essentially formed by an annular horizontal bottom 28 in the shape of an annular horizontal plate, the lower face of which is attached on the upper face 14 of the substrate plate 12 and in a sealed way, for example by adhesive bonding, along the annular bonding area 20 illustrated in dotted lines in FIG. 1.

The lower base part 26 for example is a part which is molded in plastic and its annular bottom 28 is completed with a radially outer lateral wall 30 which extends upwards vertically over a small height and which includes an inner tapped thread 32, as an example here.

The annular bottom 28 is pierced in its centre with a circular hole 34 which surrounds the area of the microelectrodes 16 when the lower part 26 is sealably adhered onto the upper face 14.

The very small height of the annular cylindrical lateral wall 30 allows the cells or the cell tissues to be easily placed on the area 16.

The other upper part 36 of the tank 24 is a vertical cylindrical lateral skirt, with a circular contour here, which for example is also a plastic-molded part.

The lower end section 38 of the lateral skirt 36 includes here, as an example, an outer thread 40 complementary to the inner tapped thread 32 so that the skirt 36 may be mounted and attached, or fixed, in a detachable way on the lower part 26 by screwing or unscrewing.

The detachable attachment of the skirt 36 on the lower base part 26 of course is such that, in the assembled position, the whole forms a sealed tank in its lower portion, whereby the seal may result from the cooperation of the thread 40 and of the tapped thread 32 and/or additional sealing means (not shown) such as one or more seal gaskets.

The inner diameter of lateral skirt 36 is about 27 mm and its height, here as a non-limiting example, is such that the total height of the tank is about 85 mm and is therefore capable of containing about 50 ml of perfusion liquid solution.

Generally, the height/diameter ratio of the tank is larger than or equal to 1.

The structural and geometrical design of the tank 24 in two parts, or two portions, is not limited to the embodiment which has just been described.

First of all, the lower base part may be made in a single part with all or part of the substrate plate 1.

The means for sealably and detachably attaching the upper lateral skirt 36 on the lower base part 26 may be of any suitable type for providing the function of a detachable and removable attachment on the one hand and the seal on the other hand.

Bayonet mounting, elastic joint mounting, etc., with or without any complementary seal or sealing gasket(s) will be mentioned as non-limiting examples.

Also, the constitutive material of either one and/or both parts of the tank 24 may vary without departing from the scope of the present invention.

The lateral skirt may be transparent or translucent so as to allow visual inspection through the lateral skirt and the latter may also include graduations representative of the volume of liquid contained in the tank.

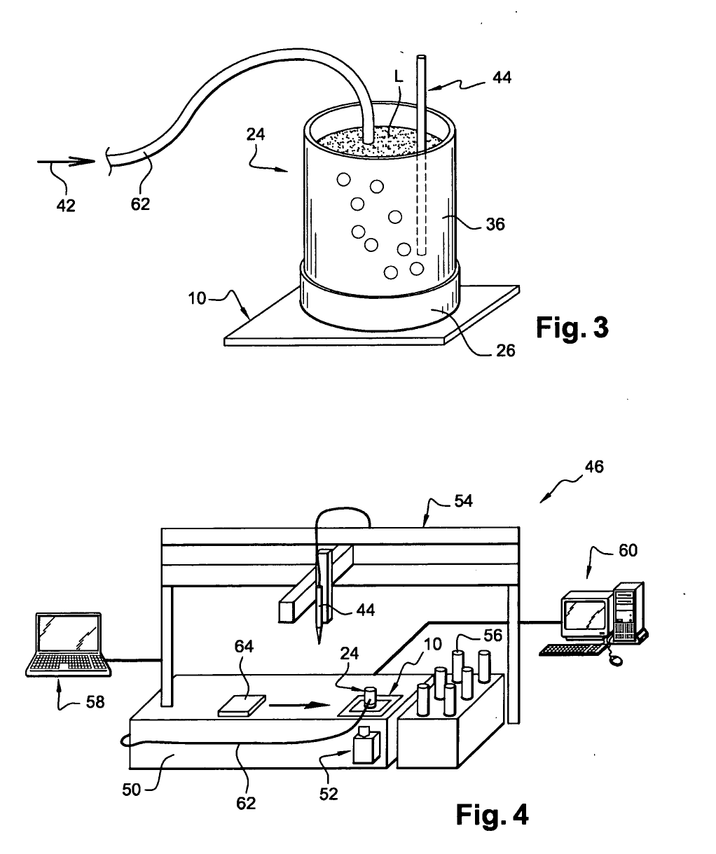

As this may be seen on the diagram of FIG. 3, the tank 24 of large height is capable of containing a large volume of perfusion liquid [symbol] L [symbol] , i.e. physiological saline, which no longer imposes any resorting to means for establishing a continuous permanent flow of the perfusion liquid in the tank.

Controlling the parameters and conditions of the perfusion liquid is carried out in situ inside the tank 24.

The apparatus according to the invention includes a vertical tube 44 which may plunge into the tank 24 and into the perfusion liquid L and which notably allows the tank 24 to be totally or partially filled, and/or totally or partially emptied.

A conduit 62 is also illustrated, which plunges into the liquid for supplying the perfusion liquid L with carbogen gas 42.

As an alternative, the continuous gas supply conduit 62 may be connected to the lateral wall of the tank.

The filling, emptying and injection of liquid(s) and/or of other products into the tank are controlled by means for automatically handling the volume and the composition of the perfusion liquid, which form a control robot or automaton.

A complete installation, also called an [symbol] automated MEA station [symbol] with which measurements may be carried out in a standardized and automated way by means of an apparatus according to the invention, is schematically illustrated in FIG. 4.

The installation 46 according to FIG. 4 includes a table or base 50 on which, as an example, a single MEA plate 10 is installed here with its tank 24 of large height.

The installation includes a monitoring camera 52, of the CCD type with an optical module for photography of the cell tissue or cells, laid on the microelectrode.

A gantry 54 is also illustrated, which bears in a mobile and controlled way along three orthogonal axes, at least one tube or needle 44 with which the tank 24 may notably be emptied and/or filled, for example from volumes of perfusion liquid, for example stored in containers or reservoirs 56 arranged beside the table 50.

Each container 56 which stores liquid to be exchanged with the one contained in a measuring tank, is of course itself also connected to a gas supply conduit such as conduit 62.

A managing laptop computer 58 for control and monitoring is further illustrated, which forms at least in part the automatic handling means, as well as another computer set 60 for collecting the results of the measurements.

A carbogen gas admission pipe 62 is schematically illustrated, as well as means 64 with which the temperature of the perfusion liquid may be controlled in the tank 24, these means 64 being connected to the computer means 60.

The invention may also find application to MEA plates with multiple tanks, each of the tanks supported by the plate may include a detachable lateral skirt according to the invention or as an alternative, the lateral skirts of different tanks may form a single detachable component according to the invention.

### CAPTIONS

10: multi-electrode plate (Multi-Electrode Array (MEA))
12: substrate plate
14: upper face of plate 12
16: microelectrodes
18: central area including microelectrodes and in which the fragment of cell tissue or cells is positioned
20: adhesive bonding area
22: electric connection pads
24: two-part perfusion tank
26: lower portion of the perfusion tank, firmly attached to the substrate plate
28: annular bottom of the tank
30: lateral wall of the annular bottom
32: internal tapped thread of the annular bottom
34: central hole of the annular bottom
36: lateral skirt forming the upper detachable portion of the perfusion tank
38: lower end section of the lateral skirt
40: external thread of the lateral skirt
42: carbogen gas
44: filling or emptying tube or needle
46: measurement installation
50: table
52: camera
54: gantry with controlled displacements
56: containers for storing perfusion liquid
58: control computer
60: computer for handling the results of measurements
62: gas supply conduit
64: means for controlling the temperature

1. An apparatus for measuring variations of extra-cellular membrane potential associated with the activity of living cells, either isolated or belonging to a cell tissue, of the type including:
a substrate plate (12);
a set (16) of microelectrodes arranged on the upper face (14) of the substrate plate (12);
a tank (24) capable of containing living cells and a perfusion liquid solution, which includes a vertical cylindrical lateral skirt (36) which is open towards the top and which surrounds an area (18) including said set (16) of microelectrodes;
characterized in that the lateral skirt (36) is attached in a sealed and detachable way with respect to the substrate plate (12).

2. The apparatus according to claim 1, characterized in that the tank (24) includes an annular bottom (28) which is added onto the substrate plate (12) and which surrounds said area (18) including said set (16) of microelectrodes.

3. The apparatus according to claim 2, characterized in that the lateral skirt (36) is attached in a sealed and detachable way on the annular bottom (28) of the tank (24).

4. The apparatus according to claim 3, characterized in that the lateral skirt (36) is screwed relatively to the substrate plate (12).

5. The apparatus according to claim 4, characterized in that the lateral skirt (36) is screwed on the annular bottom (28, 30) of the tank (24).

6. The apparatus according to claim 5, characterized in that the lower section (38) of the lateral skirt (36) of the tank (24) is screwed on a radially outer lateral wall (30) of the annular bottom (28).

7. The apparatus according to claim 1, characterized in that the tank (24) is capable of containing about 3 to 50 ml of perfusion liquid.

8. The apparatus according to claim 1, characterized in that the quotient of the height of the lateral skirt (36) divided by its largest inner dimension, is larger than or equal to 1.

9. The apparatus according to claim 1, characterized in that the lateral skirt (36) is circular cylindrical, and in that its inner diameter is larger than or equal to 5 mm (millimeters).

10. The apparatus according to claim 1, characterized in that the height of the lateral skirt (36) is less than or equal to 5 mm (millimeters).

11. The apparatus according to claim 1, characterized in that it includes means for automatically handling the volume and the composition of the perfusion liquid, of the type including a filling and emptying tube (44) which plunges vertically into the tank (24), which is connected to a robot which sequentially controls the filling and emptying of the tank (24).

12. The apparatus according to claim 11, characterized in that said tube (44) is supported by a gantry (54), the displacements of which relatively to the tank (24) are controlled along three orthogonal axes.

13. The apparatus according to claim 12, characterized in that said automatic handling means include means for controlling the temperature of the perfusion liquid.

14. The apparatus according to claim 1, characterized in that the lateral skirt (36) is screwed relatively to the substrate plate (12).
